(19) United States
(12) Patent Application Publication
(10) Pub. No.: US 2025/0054774 A1
(43) Pub. Date: Feb. 13, 2025

(54) METHOD OF MANUFACTURING SEMICONDUCTOR PACKAGE

(71) Applicant: SAMSUNG ELECTRONICS CO., LTD., Suwon-si (KR)

(72) Inventors: Hyeyeong Jo, Suwon-si (KR); Jaejeong Kim, Seoul (KR); Soowoong Park, Seoul (KR)

(73) Assignees: SAMSUNG ELECTRONICS CO., LTD., Suwon-si (KR); SEOUL NATIONAL UNIVERSITY R&DB FOUNDATION, Seoul (KR)

(21) Appl. No.: 18/439,983

(22) Filed: Feb. 13, 2024

(30) Foreign Application Priority Data
Aug. 7, 2023 (KR) 10-2023-0103104

(51) Int. Cl. H01L 21/48; G03F 7/00; G03F 7/30; H01L 21/56; H01L 23/00

(52) U.S. Cl. CPC H01L 21/4857; G03F 7/0035; G03F 7/30; H01L 21/56; H01L 24/81; H01L 2224/81

(57) ABSTRACT

According to aspects of the inventive concepts, there is provided a method of manufacturing a semiconductor package, the method including forming a conductive layer on a first redistribution substrate, forming, on the conductive layer, a resist film having an opening, wherein the opening extends through the resist film to expose an organic residue, and wherein an oxide film is provided between the conductive layer and the organic residue, removing the organic residue by adding an alcohol solution into the opening, removing the oxide film by adding an acid solution into the opening, and forming a conductive post in the opening, wherein the oxide film is provided on the conductive layer, and the oxide film and the conductive layer include a same metal material.

### CROSS-REFERENCE TO RELATED APPLICATION

This application is based on and claims priority under 35 U.S.C. § 119 to Korean Patent Application No. 10-2023-0103104, filed on Aug. 7, 2023, in the Korean Intellectual Property Office, the disclosure of which is incorporated by reference herein in its entirety.

### BACKGROUND

The inventive concepts relate to a semiconductor package, and more particularly, to a semiconductor package including a conductive post and a method of manufacturing the semiconductor package.

Semiconductor packages include integrated circuit chips implemented in forms suitable for use in electronic products. Generally, in semiconductor packages, a semiconductor chip is mounted on a printed circuit board, and the semiconductor chip and the printed circuit board are electrically connected by using a bonding wire or bumps. As the electronics industry has developed, various studies have been conducted to improve the reliability of semiconductor packages.

### SUMMARY

The inventive concepts provide a semiconductor package with improved electrical characteristics, reliability, and durability, and a method of manufacturing the same.

According to aspects of the inventive concepts, there is provided a method of manufacturing a semiconductor package, the method including forming a conductive layer on a first redistribution substrate, forming, on the conductive layer, a resist film having an opening, wherein the opening extends through the resist film to expose an organic residue, and wherein an oxide film is provided between the conductive layer and the organic residue, removing the organic residue by adding an alcohol solution into the opening, removing the oxide film by adding an acid solution into the opening, and forming a conductive post in the opening, wherein the oxide film is provided on the conductive layer, and the oxide film and the conductive layer include a same metal material.

According to aspects of the inventive concepts, there is provided a method of manufacturing a semiconductor package, the method including forming a conductive seed layer on a redistribution substrate, forming a resist film on the conductive seed layer, forming an opening extending through the resist film, wherein the opening exposes an organic residue, and wherein an oxide film is provided between the conductive seed layer and the organic residue, performing a pre-processing process in the opening, and forming a conductive structure in the opening after the pre-processing process, wherein the performing of the pre-processing process includes performing a first pre-processing process to remove the organic residue, and performing a second pre-processing process, after the first pre-processing process, to remove the oxide film.

According to aspects of the inventive concepts, there is provided a method of manufacturing a semiconductor package, the method including forming a first redistribution substrate including a first insulating layer, a first seed pattern, a first redistribution pattern on the first seed pattern, and a first redistribution pad on the first redistribution pattern, forming a conductive seed layer on the first insulating layer and the first redistribution pad, forming a resist film on the conductive seed layer, forming an opening in the resist film, wherein the opening exposes at least one of an oxide film or an organic residue, removing the organic residue by performing a first pre-processing process in the opening, wherein an alcohol solution is used in the first pre-processing process, removing the oxide film by performing a second pre-processing process in the opening, wherein an acid solution is used in the second pre-processing process, and forming a conductive post by performing a plating process in the opening, wherein the opening vertically overlaps a portion of the conductive seed layer, wherein the oxide film is formed on the portion of the conductive seed layer, and the oxide film and the conductive seed layer include a same metal material, wherein the organic residue is formed on a first portion of the oxide film while the opening is formed, wherein the organic residue and the resist film include a same material, wherein the first pre-processing process is performed before the second pre-processing process, and wherein the second pre-processing process is performed before the plating process.

### BRIEF DESCRIPTION OF THE DRAWINGS

Embodiments will be more clearly understood from the following detailed description taken in conjunction with the accompanying drawings in which:

FIGS. 1A to 1Q are diagrams for describing a method of manufacturing a semiconductor package, according to some embodiments;

FIG. 2A is a diagram for describing an oxide film according to some embodiments;

FIG. 2B is a diagram for describing an oxide film and a conductive seed layer after a first pre-processing process and a second pre-processing process, according to some embodiments;

FIG. 3 is a diagram for describing a semiconductor package according to some embodiments; and

FIG. 4 is a diagram for describing a semiconductor package according to some embodiments.

### DETAILED DESCRIPTION

Throughout the present specification, same reference numerals may denote same components. A semiconductor package and a method of manufacturing the semiconductor package, according to the inventive concepts, will be described.

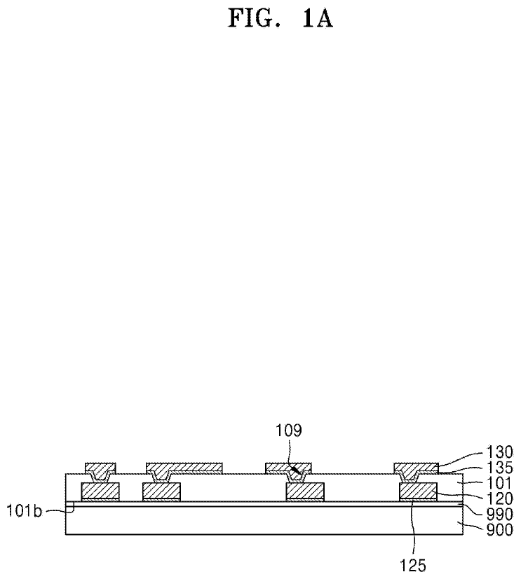

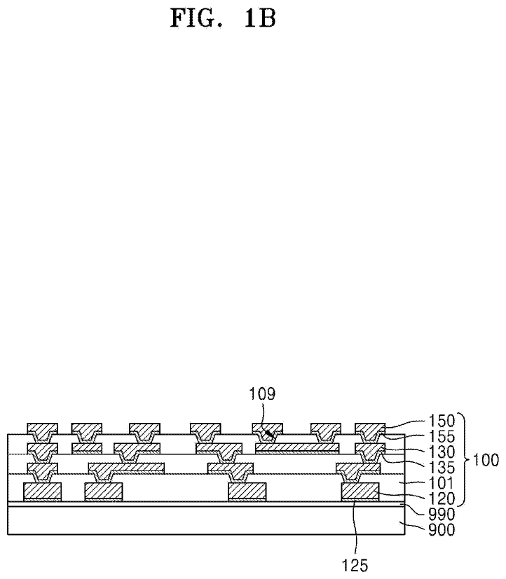

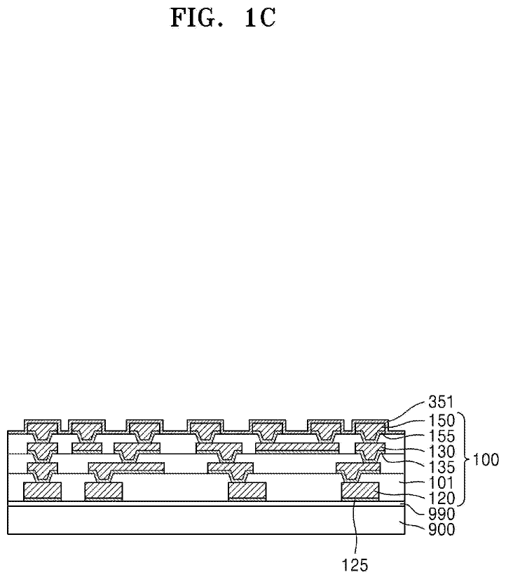

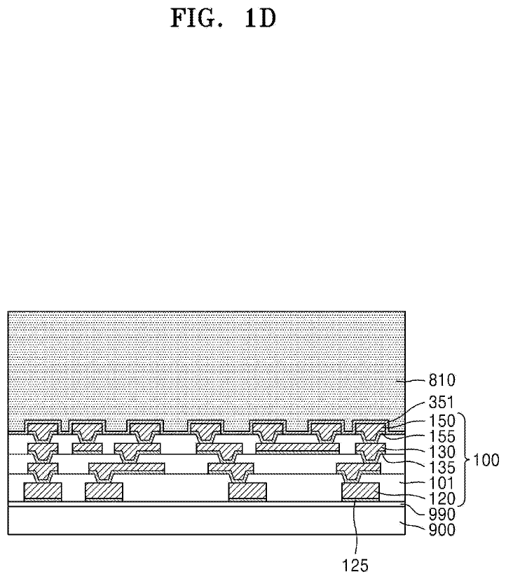

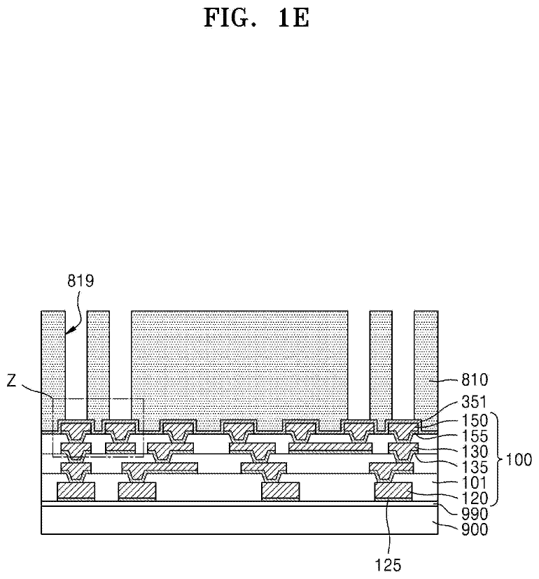

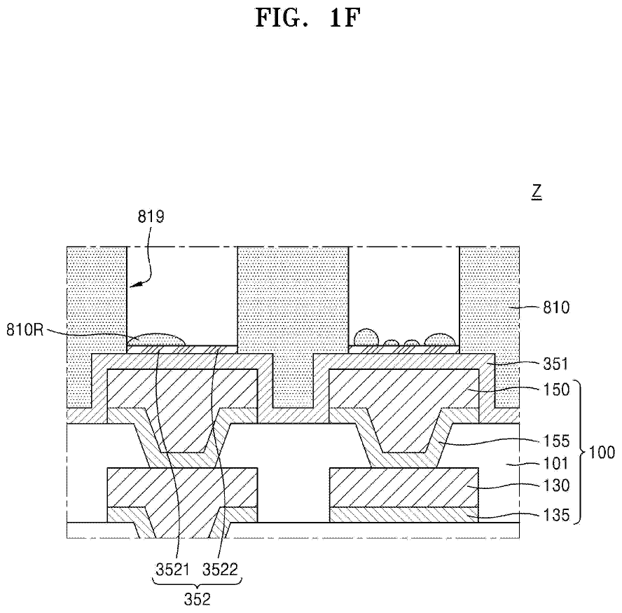

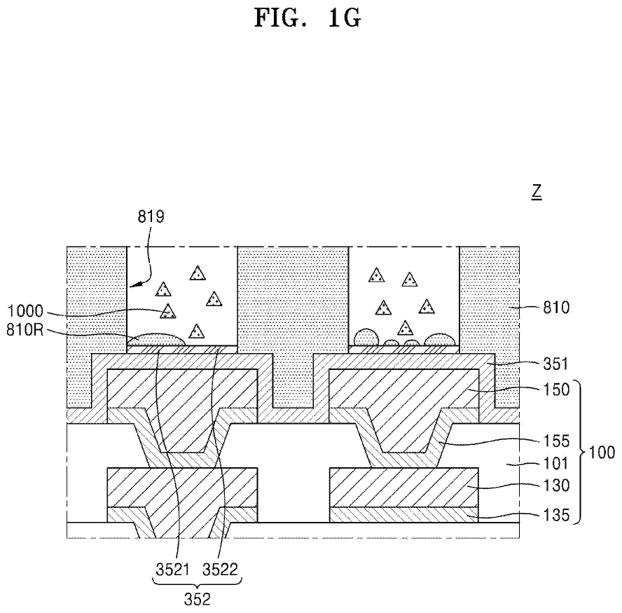

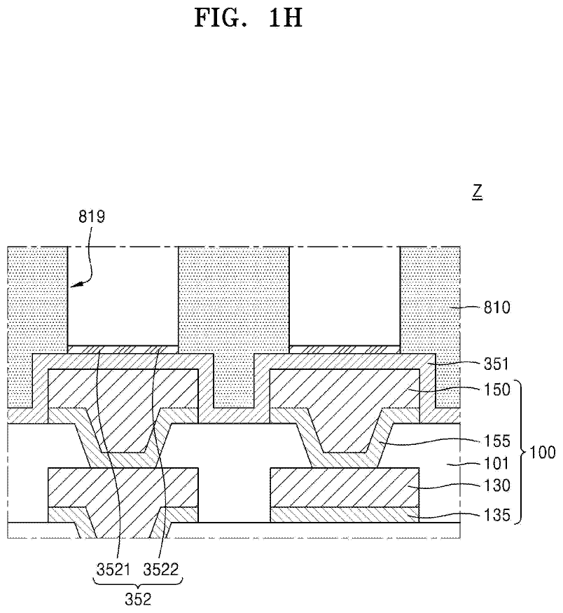

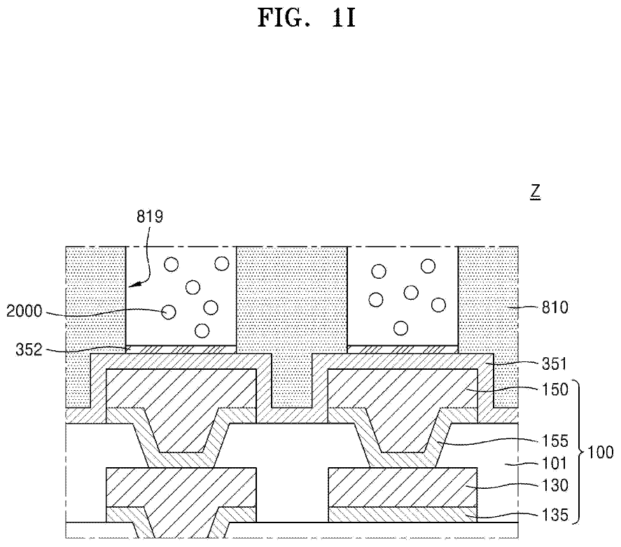

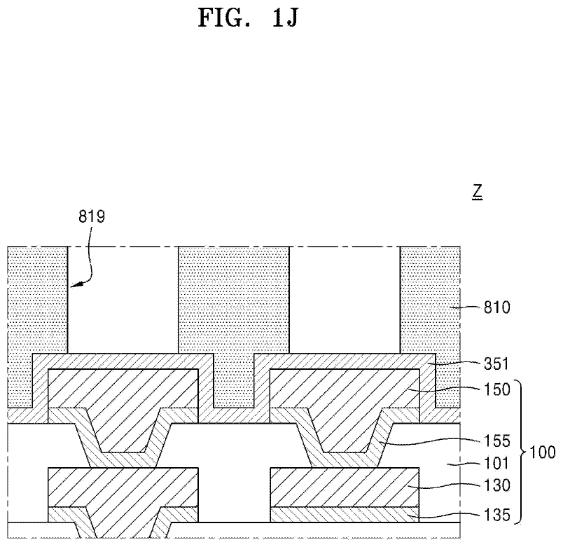

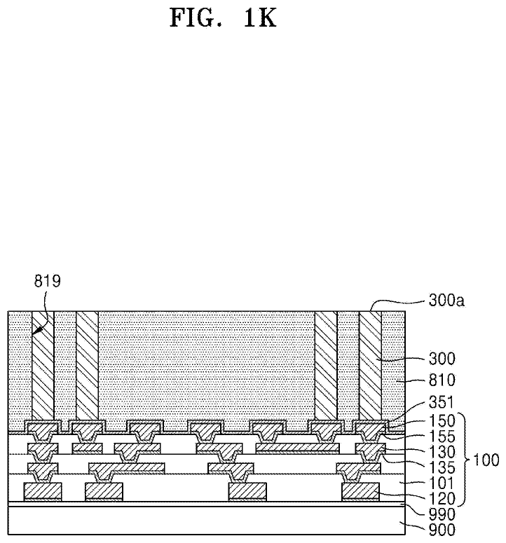

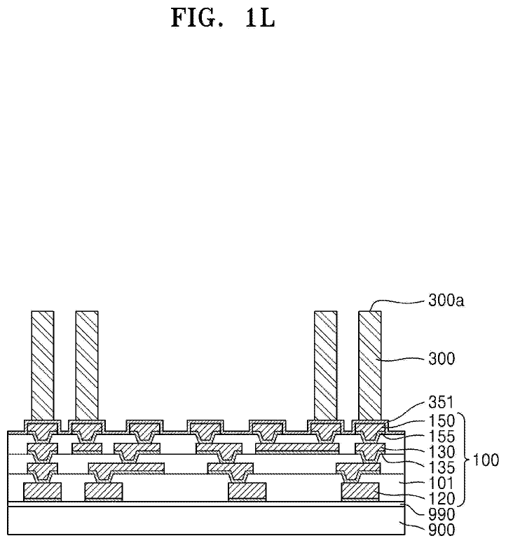

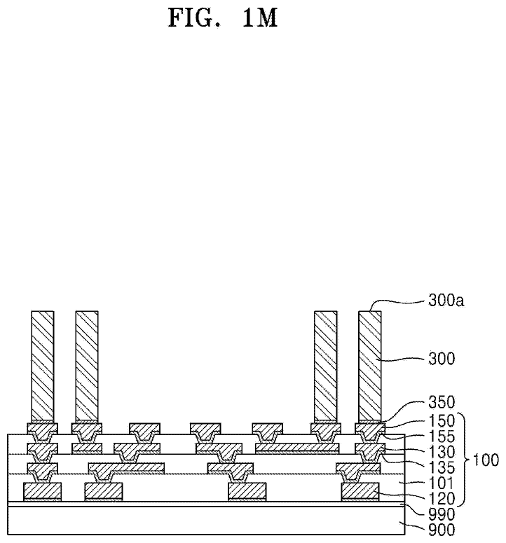

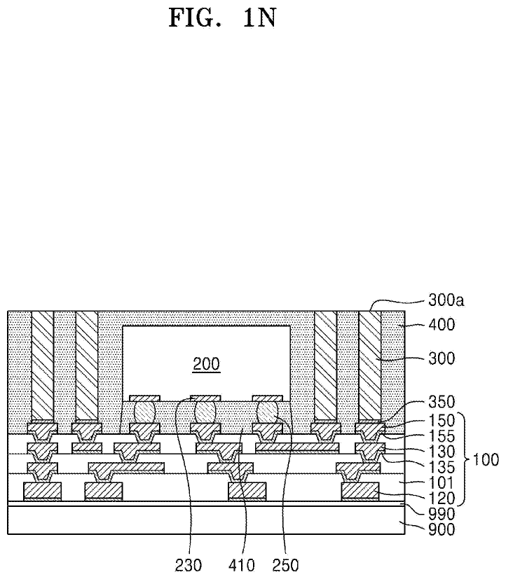

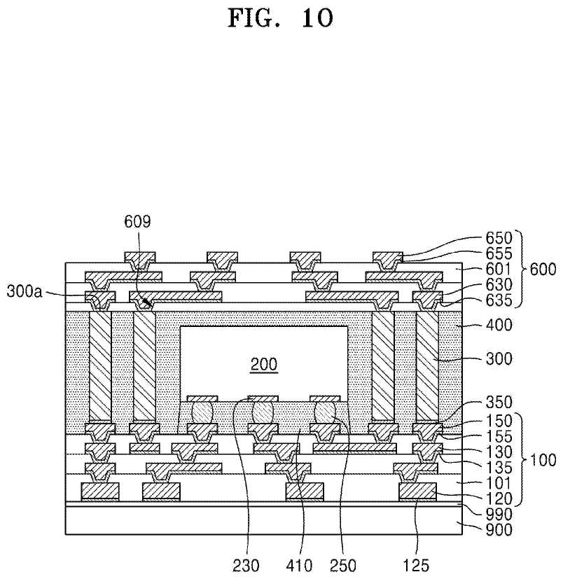

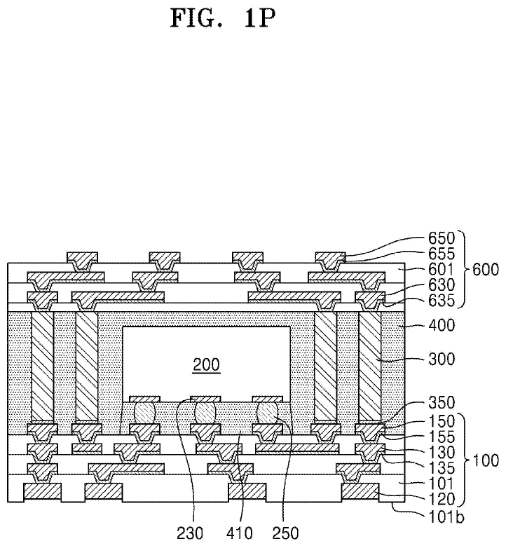

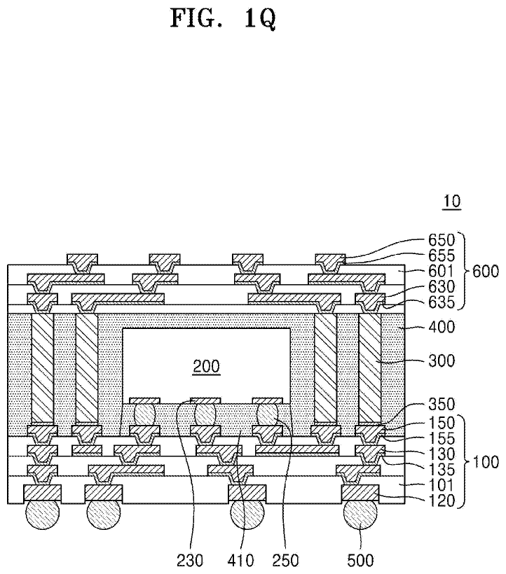

FIGS. 1A to 1Q are diagrams for describing a method of manufacturing a semiconductor package according to some embodiments. FIGS. 1F to 1J are diagrams of an enlarged image of a region Z shown in FIG. 1E.

Referring to FIG. 1A, under-bump seed patterns 125, under-bump patterns 120, a first insulating layer 101, first seed patterns 135, and first redistribution patterns 130 may be formed on a carrier substrate 900. A carrier adhesive layer 990 may be further formed between the carrier substrate 900 and the first insulating layer 101 and between the carrier substrate 900 and the under-bump patterns 120. The carrier adhesive layer 990 may attach the first insulating layer 101 and the under-bump patterns 120 to the carrier substrate 900. The carrier adhesive layer 990 may include a release layer.

According to some embodiments, the under-bump patterns 120 may be respectively formed on the under-bump seed patterns 125. The under-bump patterns 120 may be formed through an electroplating process in which the under-bump seed patterns 125 are used. The under-bump seed patterns 125 may include a conductive seed material. The conductive seed material may include copper, titanium, and/or an alloy thereof. The under-bump patterns 120 may be laterally spaced apart from one another, and may be electrically insulated from one another. Two components laterally spaced apart from each other may indicate that the components are spaced apart from each other in a horizontal direction. For example, the horizontal direction may be a direction parallel to a bottom surface 101b of the first insulating layer 101. The under-bump patterns 120 may include a metal material such as copper.

The first insulating layer 101 may be formed on the carrier adhesive layer 990 and may be on (e.g., may cover) sidewalls and top surfaces of the under-bump patterns 120. The first insulating layer 101 may include, for example, an organic material such as a photo-imageable dielectric (PID) material. The PID material may include a polymer. The PID may include, for example, at least one of photosensitive polyimide, polybenzoxazole, a phenol-based polymer, or a benzocyclobutene-based polymer. First holes 109 may be formed in the first insulating layer 101 to expose the under-bump patterns 120.

Forming the first seed patterns 135 and the first redistribution patterns 130 may include forming a first seed layer in the first holes 109 and on a top surface of the first insulating layer 101, forming, on the first seed layer, a resist pattern (not shown) having guide holes, performing an electroplating operation in which the first seed layer is used as an electrode, exposing a portion of the first seed layer by removing the resist pattern, and etching the exposed portion of the first seed layer. The guide holes may be respectively connected to the first holes 109. The first redistribution patterns 130 may be formed in the first holes 109 and the guide holes through the electroplating process. By etching the first seed layer, the first seed patterns 135 may be respectively formed on bottom surfaces of the first redistribution patterns 130.

The first seed patterns 135 may include a material different from the materials included in the under-bump patterns 120 and the first redistribution patterns 130. For example, the first seed patterns 135 may include a conductive seed material.

The first redistribution patterns 130 may be respectively provided on the under-bump patterns 120 and may be electrically connected to the under-bump patterns 120, respectively. The first redistribution patterns 130 may be laterally spaced apart from one another, and may be electrically insulated from one another. The first redistribution patterns 130 may include a metal such as copper.

Each of the first redistribution patterns 130 may include a first via portion and a first wiring portion. The first via portion may be provided in the first insulating layer 101. A width of a top surface of the first via portion may be greater than a width of a bottom surface of the first via portion. The first wiring portion may be provided on the first via portion and may be connected to the first via portion without a boundary surface. A width of the first wiring portion may be greater than a width of the top surface of the first via portion. The first wiring portion may extend onto the top surface of the first insulating layer 101. In the present specification, a level may indicate a vertical level, and a difference in levels may be measured in a direction perpendicular to a bottom surface 101b of the first insulating layer 101. “Vertical” may indicate being vertical to the bottom surface 101b of the first insulating layer 101.

Referring to FIG. 1B, a process of forming the first insulating layer 101, a process of forming the first seed patterns 135, and a process of forming the first redistribution patterns 130 may be repeatedly performed. By doing so, a plurality of the first insulating layer 101 that have been stacked and a plurality of the first redistribution patterns 130 that have been stacked may be formed. The number of the first insulating layers 101 that have been stacked may be variously modified. For example, the first insulating layers 101 may include a same material. Boundary surfaces between the first insulating layers 101 adjacent each other may be not distinguished.

First seed pads 155 may be formed in the first holes 109 of an uppermost portion of the first insulating layer 101. For example, first redistribution pads 150 may be formed by performing the electroplating process in which the first seed pads 155 are used as electrodes. By doing so, a first redistribution substrate 100 may be manufactured. The first redistribution substrate 100 may include the first insulating layers 101, the under-bump patterns 120, the first seed patterns 135, the first redistribution patterns 130, the first seed pads 155, and the first redistribution pads 150. In the present specification, being in contact with the first redistribution substrate 100 may include being in contact with at least one of the first redistribution patterns 130 or the first redistribution pads 150.

The first redistribution pads 150 may be disposed on the first redistribution patterns 130 and may be respectively in contact with (e.g., may be respectively electrically connected to) the first redistribution patterns 130. The first redistribution pads 150 may be laterally spaced apart from each other. As the first redistribution patterns 130 are provided, at least one first redistribution pad 150 may be not electrically aligned with the under-bump pattern 120 electrically connected thereto. Accordingly, arrangements of the under-bump patterns 120 and the first redistribution pads 150 may be more freely designed.

The first redistribution pads 150 may be provided in the uppermost portion of the first insulating layer 101 and may extend onto a top surface of the uppermost portion of the first insulating layer 101. A bottom portion of each of the first redistribution pads 150 may be disposed in the uppermost portion of the first insulating layer 101. A top portion of each of the first redistribution pads 150 may extend onto the top surface of the uppermost portion of the first insulating layer 101. The top portion of each of the first redistribution pads 150 may have a width greater than a width of the bottom portion of each of the first redistribution pads 150. The first redistribution pads 150 may include copper, nickel, gold, and/or alloys thereof.

The first seed pads 155 may be respectively provided on bottom surfaces of the first redistribution pads 150. The first seed pads 155 are provided between uppermost portions of first redistribution pads 150 and the first redistribution patterns 130 and may extend between the uppermost portion of the first insulating layer 101 and the first redistribution pads 150. The first seed pads 155 may be laterally spaced apart from each other. The first seed pads 155 may include a material different from a material included in the first redistribution pads 150. The first seed pads 155 may include, for example, a conductive seed material.

Referring to FIG. 1C, a conductive layer may be formed on a top surface of the first redistribution substrate 100 and may be on (e.g., may cover) the first redistribution pads 150 and the uppermost portion of the first insulating layer 101. The conductive layer may include a conductive seed layer 351. For example, the conductive seed layer 351 may be on (e.g., may cover) sidewalls and top surfaces of the first redistribution pads 150 and the top surface of the uppermost portion of the first insulating layer 101. The conductive seed layer 351 may include a material different from the material of the first redistribution pads 150. The conductive seed layer 351 may include a conductive seed material.

Referring to FIG. 1D, a resist film 810 may be formed on a top surface of the conductive seed layer 351. The resist film 810 may include, but is not limited to, an organic material such as a polymer.

Referring to FIGS. 1E and 1F, openings 819 may be formed in the resist film 810. The forming of the openings 819 may include removing a portion of the resist film 810. For example, the openings 819 may be formed by patterning the resist film 810 through a process of exposure and development. The openings 819 may vertically overlap the first redistribution pads 150. As used herein, “an element A vertically overlaps an element B” (or similar language) means that there is at least one line that extends in a vertical direction and intersects both the elements A and B. The openings 819 may extend through the resist film 810. The openings 819 may expose a first portion of the conductive seed layer 351. Impurities may be formed on the exposed first portion of the conductive seed layer 351. The impurities may include an oxide film 352 and organic residues 810R. As shown in FIG. 1F, the oxide film 352 may be formed on the conductive seed layer 351 that has been exposed through the openings 819. For example, the oxide film 352 may be formed during or after the forming of the openings 819. The oxide film 352 may be formed as the conductive seed layer 351 is in contact with air (e.g., oxygen) or water. The oxide film 352 may include a metal identical to a metal included in the conductive seed layer 351. That is, the oxide film 352 and the conductive seed layer 351 may include a same metal material.

In the process of forming the openings 819, the organic residues 810R may be formed in the openings 819. The organic residues 810R may include residues of the resist film 810. The organic residues 810R may include a material identical to the material included in the resist film 810. That is, the organic residues 810R and the resist film 810 may include a same material. The oxide film 352 may include a first portion 3521 and a second portion 3522. The organic residues 810R may be on the first portion 3521 of the oxide film 352. As the organic residues 810R are not provided on the second portion 3522 of the oxide film 352, the second portion 3522 of the oxide film 352 may be exposed through the openings 819. That is, the organic residues 810R may be separated from a top surface of the second portion 3522 of the oxide film 352. Arrangement of the first portion 3521 and the second portion 3522 of the oxide film 352 may be determined according to positions at which the organic residues 810R are generated. Unlike in the drawing, in some embodiments, the oxide film 352 may not include the second portion 3522, and the organic residues 810R may completely cover the top surface of the oxide film 352 exposed through the openings 819.

Hereinafter, a first pre-processing process and a second pre-processing process according to some embodiments will be described. The first pre-processing process and the second pre-processing process may include pre-processing processes of conductive posts. Regarding descriptions with reference to FIGS. 1G to 1J, refer also to FIG. 1E.

Sequentially referring to FIGS. 1G and 1H, the first pre-processing process may be performed in the openings 819 to remove the organic residues 810R. Performing the first pre-processing process may include adding an alcohol solution 1000 into the openings 819 and on the organic residues 810R. The organic residues 810R may be removed by the alcohol solution 1000. For example, the organic residues 810R may be separated from the oxide film 352 by the alcohol solution 1000 and form organic residual particles (not shown). The organic residual particles may be discharged outside from the openings 819. By removal of the organic residues 810R, the first portion 3521 of the oxide film 352 may be exposed. Once the first pre-processing process is complete, the organic residues 810R may not remain in the openings 819.

The alcohol solution 1000 may include alcohol and water. For example, alcohol may include ethanol. As another example, alcohol may include methanol, propanol, butanol, pentanol, hexanol, and/or heptanol. The alcohol may include alcohol having one to ten carbon atoms, but is not limited thereto. An alkyl group of the alcohol may include a linear alkyl group or a branched alkyl group. Water may be used as a solvent.

The alcohol solution 1000 may include about 40% to about 60% of alcohol. When the alcohol solution 1000 includes less than 40% or more than 60% of alcohol, it may be difficult to properly remove the organic residues 810R. According to some embodiments, the first pre-processing process is performed using about 40% to about 60% of alcohol, and therefore, the organic residues 810R may be well removed.

The first pre-processing process may be performed for about thirty seconds to about ninety seconds. For example, the alcohol solution 1000 may be applied into the openings 819 for about thirty seconds to about ninety seconds. As the first pre-processing process is performed for thirty seconds or longer, the alcohol solution 1000 may properly remove the organic residues 810R. As the first pre-processing process is performed for not more than ninety seconds, the efficiency in the process of manufacturing the semiconductor package may be improved.

After the first pre-processing process, a first cleaning process may be further performed. The first cleaning process may be performed on the oxide film 352 that has been exposed. For example, the first cleaning process may be performed on a top surface of the first portion 3521 that has been exposed and the second portion 3522 of the oxide film 352. The first cleaning process may be performed using water such as deionized water (D.I. water). For example, D.I. water may be applied into the openings 819 and the oxide film 352 that has been exposed. Through the first cleaning process, the alcohol solution 1000 and/or the organic residual particles may be removed from the openings 819.

Sequentially referring to FIGS. 11 and 1J, the second pre-processing process may be performed in the openings 819 to remove the oxide film 352. Performing the second pre-processing process may include adding an acid solution 2000 into the openings 819 and on the oxide film 352. The oxide film 352 may be removed by the acid solution 2000. The acid solution 2000 may include a weak acid. A pKa of the weak acid may be 2.58 or more. For example, the acid solution 2000 may include citric acid. As another example, the acid solution 2000 may include acetic acid or tartaric acid. A molar concentration of the acid in the acid solution 2000 may be from about 0.1 M to about 5 M. For example, the second pre-processing process may be performed using citric acid having a molar concentration from about 0.1 M to about 5 M.

The second pre-processing process may be performed for about thirty seconds to about ninety seconds. For example, the citric acid 2000 may be applied into the openings 819 for about thirty seconds to about ninety seconds. As the second pre-processing process is performed for thirty seconds or more, the acid solution 2000 may properly remove the oxide film 352. As the second pre-processing process is performed for ninety seconds or less, the efficiency of the second pre-processing process may be improved.

When the second pre-processing process is performed prior to the first pre-processing process, during the second pre-processing process, the second portion 3522 of the oxide film 352 exposed through the organic residues 810R (see FIG. 1F) may be removed, but the first portion 3521 of the oxide film 352 covered by the organic residues 810R may be not removed. Next, even when the first pre-processing process is performed, the organic residues 810R may be removed, but the first portion 3521 of the oxide film 352 may remain without being removed. According to some embodiments, as the second pre-processing process is performed after the first pre-processing process, after the organic residues 810R are removed, the oxide film 352 may be removed. Accordingly, not only the second portion 3522 of the oxide film 352 but also the first portion 3521 may be properly removed.

Referring again to FIG. 1J, after the second pre-processing process, a second cleaning process may be further performed. The second cleaning process may be performed in the openings 819 and on the conductive seed layer 351. The second cleaning process may be performed using water such as D.I. water. For example, D.I. water may be applied into the opening 819. Even when residues of the acid solution 2000 (see FIG. 1I) or the oxide film 352 remain in the openings 819 after the second pre-processing process, through the second cleaning process, the acid solution 2000 and/or the oxide film 352 may be removed from the conductive seed layer 351 in the openings 819. Accordingly, as shown in FIGS. 1J and 1E, the top surface of the conductive seed layer 351 may be exposed by the openings 819. The oxide film 352 (see FIG. 1F) and the organic residues 810R (see FIG. 1F) may not remain in the openings 819 and on the conductive seed layer 351.

Referring to FIG. 1K, conductive structures may be formed in the openings 819 and on the conductive seed layer 351. The conductive structures may include conductive posts 300. The conductive posts 300 may have a pillar shape, but are not limited thereto. Forming the conductive posts 300 may include performing a plating process in which the conductive seed layer 351 is used as an electrode. The plating process may include an electroplating process. For example, the electroplating process may be performed using a plating solution. The plating solution may include copper sulfate (CuSO₄), sulfuric acid (H₂SO₄), and hydrochloric acid (HCl). The electroplating process may be finished before the conductive posts 300 extend onto the top surface of the resist film 810. Top surfaces 300a of the conductive posts 300 may be provided at a level equal to or lower than a level of the top surface of the resist film 810. Accordingly, in the process of forming the conductive post 300, an additional planarization process may not be required. A process of manufacturing the conductive posts 300 may be simplified. For example, the plating process may be performed for about 1,800 seconds to about 8,000 seconds, but is not limited thereto. The conductive posts 300 may include a metal material, e.g., copper.

When impurities such as the oxide film 352 or the organic residues 810R remain on the conductive seed layer 351 as shown in FIG. 1F, the oxide film 352 and the organic residues 810R may operate as defects in the plating process. The conductive posts 300 may be improperly formed. For example, the top surfaces of the conductive posts 300 may be not flat, or the conductive posts 300 may have non-uniform shapes. In addition, when the impurities remain on bottom surfaces of the conductive posts 300, electrical characteristics between the conductive posts 300 and the first redistribution pads 150 may be poor.

According to some embodiments, during the first pre-processing process, the organic residues 810R may be removed by the alcohol solution 1000, as shown in FIG. 1G; and during the second pre-processing process, the oxide film 352 may be removed by the acid solution 2000, as shown in FIG. 1I. Accordingly, the organic residues 810R and the oxide film 352 may not remain in the openings 819 and on the conductive seed layer 351. Accordingly, through the electroplating process, the conductive posts 300 may be properly formed on the conductive seed layer 351. For example, the conductive posts 300 may have the top surfaces 300a having a flat shape, and may have a favorable shape. As the impurities are not provided between the bottom surfaces of the conductive posts 300 and the first redistribution pads 150, the conductive posts 300 and the first redistribution pads 150 may be electrically well connected to each other.

Referring to FIG. 1L, as the resist film 810 is removed, the top surfaces of the conductive seed layers 351 and sidewalls of the conductive posts 300 may be exposed. The removing of the resist film 810 may be performed through a strip process.

Referring to FIG. 1M, the conductive seed layer 351 may be patterned, and conductive seed patterns 350 may be formed. Patterning of the conductive seed layer 351 may be performed through an etching process. The conductive seed layer 351 may include a first portion and second portions. A top surface of the first portion of the conductive seed layer 351 may be exposed through the conductive posts 300. The second portions of the conductive seed layer 351 may be provided on the bottom surfaces of the conductive posts 300. Through the etching process, the first portion of the conductive seed layer 351 may be removed, and the first redistribution substrate 100 may be exposed. For example, the uppermost portion of the first insulating layer 101 and the first redistribution pads 150 may be exposed. In the etching process, the conductive posts 300 may have an etching selectivity with respect to the conductive seed layer 351. The second portions of the conductive seed layer 351 may be not exposed in the etching process. After the etching process is finished, the second portions of the conductive seed layer 351 may form the conductive seed patterns 350. The conductive seed patterns 350 may be disposed apart from one another, and may be electrically separated from one another.

Referring to FIG. 1N, a semiconductor chip 200 may be mounted on the first redistribution substrate 100. For example, the semiconductor chip 200 may be provided on a top surface of a center region of the first redistribution substrate 100. The semiconductor chip 200 may be laterally spaced apart from the conductive posts 300. The semiconductor chip 200 may include any one of a logic chip, a buffer chip, and a memory chip. For example, the semiconductor chip 200 may include a logic chip. The semiconductor chip 200 may include an application specific integrated circuit (ASIC) chip or an application processor (AP) chip. The ASIC chip may include an application specific integrated circuit (ASIC). As another example, the semiconductor chip 200 may include a central processing unit (CPU) or a graphic processing unit (GPU). Unlike in the drawing, a plurality of semiconductor chips 200 may be mounted on the top surface of the first redistribution substrate 100.

Mounting the semiconductor chip 200 may include forming bumps 250 between the first redistribution substrate 100 and the semiconductor chip 200. The bumps 250 may be in contact with the first redistribution pads 150 and chip pads 230 of the semiconductor chip 200. The bumps 250 may include solder balls, and the solder balls may include a solder material. The bumps 250 may further include pillar patterns.

An underfill film 410 may be further formed in a gap region between the first redistribution substrate 100 and the semiconductor chip 200 to be on (e.g., to cover) sidewalls of the bumps 250. The underfill film 410 may include an insulating polymer, e.g., an epoxy polymer.

A molding film 400 may be formed on the top surface of the first redistribution substrate 100 to be on (e.g., to cover) the semiconductor chip 200 and the conductive posts 300. A top surface of the molding film 400 may be coplanar with top surfaces 300a of the conductive posts 300. The molding film 400 may include an insulating polymer such as an epoxy molding compound. The molding film 400 may include an insulating polymer different from an insulating polymer included in the underfill film 410. As another example, the underfill film 410 may be omitted, and the molding film 400 may further extend to the gap region between the first redistribution substrate 100 and the semiconductor chip 200.

Referring to FIG. 1O, a second redistribution substrate 600 may be formed on the molding film 400 and the conductive posts 300. According to some embodiments, a second insulating layer 601 may be formed on a top surface of the molding film 400. Second holes 609 may be formed in the second insulating layer 601 to expose each of the top surfaces 300a of the conductive posts 300. Second seed patterns 635 may be conformally formed in the second holes 609 and may be on a surface of the second insulating layer 601. Second redistribution patterns 630 may be formed in the second holes 609 and on the surface of the second insulating layer 601 to be on (e.g., to cover) the second seed patterns 635.

Each of the second redistribution patterns 630 may include a second via portion and a second wiring portion. The second via portion may be formed in the second hole 609 corresponding thereto. The second wiring portion may be formed on the second via portion and may extend onto the surface of the second insulating layer 601. A method of forming the second seed patterns 635 and the second redistribution patterns 630 may be identical or similar to the descriptions of embodiments of forming the first seed patterns 135 and the first redistribution patterns 130 shown in FIG. 1A. A process of forming the second insulating layer 601, a process of forming the second seed patterns 635, and a process of forming the second redistribution patterns 630 may be repeatedly performed. Accordingly, a plurality of the second insulating layers 601 in a stack, a plurality of the second seed patterns 635, and a plurality of the second redistribution patterns 630 in a stack may be formed. For example, the second redistribution patterns 630 may include a metal such as copper. The second seed patterns 635 may include a material different from the material included in the second redistribution patterns 630. For example, the second seed patterns 635 may include a conductive seed material.

Second redistribution pads 650 may be formed in an uppermost portion of the second insulating layer 601 and on a top surface of the uppermost portion of the second insulating layer 601. For example, the second redistribution pads 650 may include a metal such as copper. Before the forming of the second redistribution pads 650, second seed pads 655 may be formed. The second seed pads 655 may include a metal different from the metal included in the second redistribution pads 650. The second seed pads 655 may include a conductive seed material. The second redistribution pads 650 may be formed through an electroplating process in which the second seed pads 655 are used as electrodes. By doing so, the second redistribution substrate 600 may be manufactured. The second redistribution substrate 600 may include the second insulating layers 601, the second seed patterns 635, the second redistribution patterns 630, the second seed pads 655, and the second redistribution pads 650.

The second redistribution substrate 600 may be electrically connected to the conductive posts 300. In the present specification, being in contact with the second redistribution substrate 600 may include being in contact with at least one of the second redistribution patterns 630.

Referring to FIG. 1P, the carrier substrate 900 and the carrier adhesive layer 990 may be removed, and the bottom surface of the first redistribution substrate 100 may be exposed. For example, a bottom surface 101b of a lowermost portion of the first insulating layer 101 and bottom surfaces of the under-bump seed patterns 125 may be exposed. By removing the under-bump seed patterns 125 that have been exposed, the bottom surfaces of the under-bump patterns 120 may be exposed. The removing of the under-bump seed patterns 125 may be performed through an etching process.

Referring to FIG. 1Q, solder balls 500 may be respectively formed on the bottom surfaces of the under-bump patterns 120 and may be in contact with the under-bump patterns 120. The manufacturing of the semiconductor package 10 may be finished according to embodiments described above.

According to some embodiments, after performing the first pre-processing process and the second pre-processing process as described with reference to embodiments shown in FIGS. 1G to 1J, the conductive posts 300 may be formed. Accordingly, the conductive posts 300 may be formed well. Impurities may be not provided between the bottom surfaces of the conductive posts 300 and the first redistribution pads 150. The impurities may include the oxide film 352 and/or the organic residue 810R described with reference to FIG. 1F. Accordingly, the conductive posts 300 and the first redistribution pads 150 may be electrically connected well to each other. The semiconductor package 10 may have improved reliability. The second redistribution substrate 600 may be electrically connected to the first redistribution substrate 100 through the conductive posts 300. The conductive posts 300 may function as an electrical path between the first redistribution substrate 100 and the second redistribution substrate 600. Even when the semiconductor package 10 operates for a long time, defects such as cracks may not occur between the conductive posts 300 and the conductive seed patterns 350. Accordingly, the durability of the semiconductor package 10 may be improved.

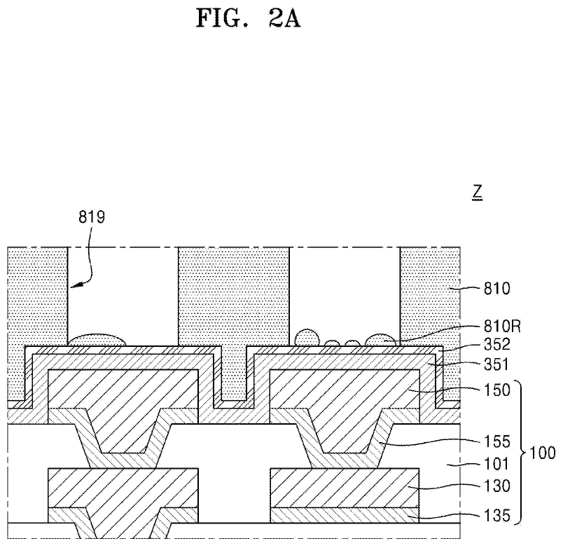

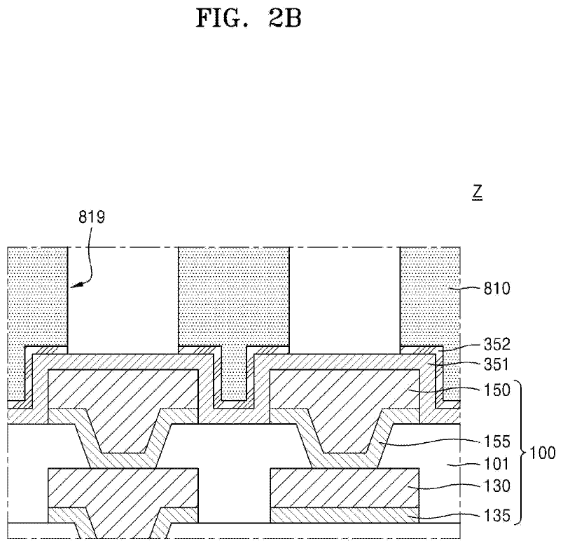

FIG. 2A is a diagram for describing an oxide film according to some embodiments, which corresponds to a diagram of an enlarged image of a region Z shown in FIG. 1E. FIG. 2B is a diagram for describing an oxide film and a conductive seed layer according to a first pre-processing process and a second pre-processing process according to some embodiments, which corresponds to a diagram of the enlarged image of the region Z shown in FIG. 1E. Hereinafter, same descriptions will not be repeatedly given.

Referring to FIG. 2A together with FIG. 1E, the openings 819 and the organic residues 810R may be formed through performance of a patterning process on the resist film 810. The organic residues 810R may be formed in the openings 819 and on the oxide film 352. The oxide film 352 may be identical or similar to the oxide film 352 described with reference to examples shown in FIG. 1F. For example, the oxide film 352 may be provided in the openings 819, and may vertically overlap the openings 819. However, the oxide film 352 may be formed before the forming of the resist film 810. Accordingly, the oxide film 352 may further extend onto the bottom surface of the resist film 810. For example, the oxide film 352 may be provided between the first redistribution pads 150 and the resist film 810 and between the uppermost portion of the first insulating layer 101 and the resist film 810.

Referring to FIG. 2B together with FIG. 1E, the first pre-processing process and the second pre-processing process may be performed in the openings 819 to remove the organic residues 810R and a portion of the oxide film 352. However, another portion of the oxide film 352 may be provided on the bottom surface of the resist film 810 and may be not exposed in the second pre-processing process. The other portion of the oxide film 352 may remain between the first redistribution substrate 100 and the resist film 810 after the second pre-processing process. The other portion of the oxide film 352 may be removed later in a process of removing the resist film 810, which is shown in FIG. 1L, or a patterning process for forming the conductive seed patterns 350 shown in FIG. 1M.

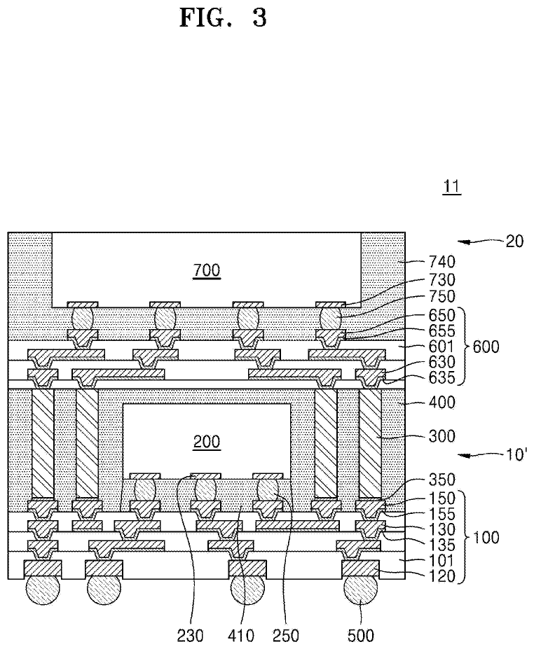

FIG. 3 is a diagram for describing a semiconductor package 11 according to some embodiments.

Referring to FIG. 3, the semiconductor package 11 may include a bottom package 10′ and a top package 20. The bottom package 10′ may be manufactured as described above with reference to the examples shown in FIGS. 1A to 1Q. The bottom package 10′ may be substantially the same as the semiconductor package 10 shown in FIG. 1Q. The bottom package 10′ may include the first redistribution substrate 100, the solder balls 500, the semiconductor chip 200, the molding film 400, the conductive posts 300, and the second redistribution substrate 600.

The top package 20 may include a top semiconductor chip 700 and top bumps 750. The top semiconductor chip 700 may include a semiconductor chip different from the semiconductor chip 200. For example, the top semiconductor chip 700 may include, but is not limited to, a memory chip. The top semiconductor chip 700 may be mounted on a top surface of the second redistribution substrate 600. For example, the top bumps 750 may be provided between the second redistribution substrate 600 and the top semiconductor chip 700. The top bumps 750 may be in contact with the second redistribution pads 650 and chip pads 730 of the top semiconductor chip 700. The top bumps 750 may include solder balls. Although not shown, the top bumps 750 may further include metal pillar patterns. The top semiconductor chip 700 may be in contact with (e.g., may be electrically connected to) the semiconductor chip 200 or the solder balls 500 through the second redistribution substrate 600 and the conductive posts 300.

The top package 20 may further include a top molding film 740. The top molding film 740 may be provided on the second redistribution substrate 600 and may be on (e.g., may cover) the top semiconductor chip 700. The top molding film 740 may expose a top surface of the top semiconductor chip 700. Unlike in the drawing, the top molding film 740 may further be on (e.g., may cover) the top surface of the top semiconductor chip 700. The top molding film 740 may include an insulating polymer such as an epoxy molding compound. As another example, the top molding film 740 may be omitted.

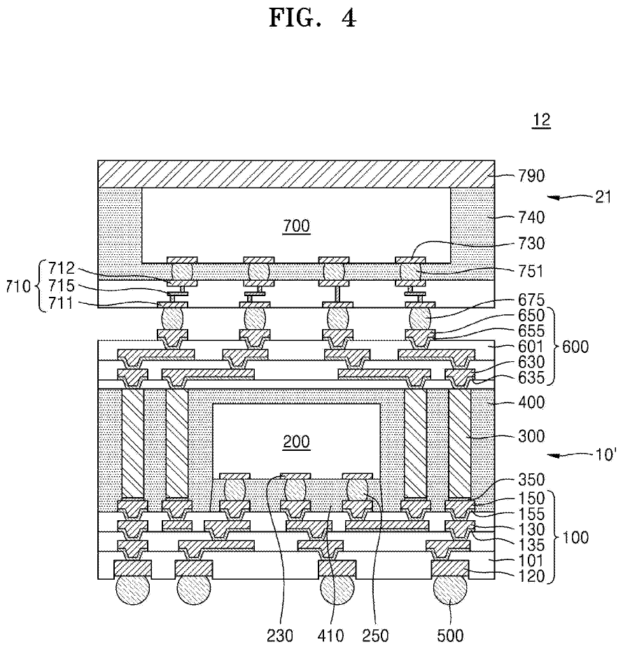

FIG. 4 is a diagram for describing a semiconductor package 12 according to some embodiments.

Referring to FIG. 4, the semiconductor package 12 may include the bottom package 10′, a top package 21, and connection terminals 675. The bottom package 10′ may be manufactured as described above with reference to the examples shown in FIGS. 1A to IQ. The bottom package 10′ may be substantially the same as the semiconductor package 10 shown in FIG. 1Q.

The top package 21 may include a top substrate 710, the top semiconductor chip 700, top conductive bumps 751, and the top molding film 740. The top substrate 710 may be disposed on the top surface of the second redistribution substrate 600 and may be spaced apart from the top surface of the second redistribution substrate 600. The top substrate 710 may include a printed circuit board (PCB) or a redistribution layer.

The top substrate 710 may include first metal pads 711, second metal pads 712, and metal wirings 715. The first metal pads 711 and the second metal pads 712 may be disposed on a bottom surface and a top surface of the top substrate 710, respectively. The metal wirings 715 may be provided in the top substrate 710 to be in contact with (e.g., electrically connected to) the first metal pads 711 and the second metal pads 712. The top conductive bumps 751 may be between the top substrate 710 and the top semiconductor chip 700, and may be in contact with the second metal pads 712 and the chip pads 730 of the top semiconductor chip 700. The top conductive bumps 751 may include a solder material. The top molding film 740 may be provided on the top substrate 710 to be on (e.g., to cover) the top semiconductor chip 700.

The connection terminals 675 may be between the second redistribution substrate 600 and the top substrate 710, and may be in contact with the second redistribution pads 650 and the first metal pads 711. The connection terminals 675 may include a solder material. Although not shown, the connection terminals 675 may further include metal pillar patterns.

The top package 20 may further include a heat-radiating structure 790. The heat-radiating structure 790 may be disposed on the top surface of the top semiconductor chip 700 and a top surface of the top molding film 740. The heat-radiating structure 790 may further extend onto a side surface of the top molding film 740. The heat-radiating structure 790 may include a heat sink, a heat slug, or a thermal interface material (TIM) layer. The heat-radiating structure 790 may include, for example, a metal.

Embodiments of the present disclosure may be combined with one another. For example, the semiconductor package 10 shown in FIG. 1Q, the semiconductor package 11 shown in FIG. 3, and the semiconductor package 12 shown in FIG. 4 may be combined with one another. For example, the semiconductor package 11 shown in FIG. 3 may further include the heat-radiating structure 790 shown in FIG. 4.

According to the inventive concepts, as the pre-processing process is performed in the opening of the resist film, the organic residues and the oxide film may be removed, and the top surface of the conductive seed layer may be exposed. Next, the conductive structure including the conductive post may be formed in the opening and on the exposed top surface of the conductive seed layer. Accordingly, the conductive structure may be formed well. The semiconductor package may thus have improved electrical characteristics and improved durability.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

While the inventive concepts have been particularly shown and described with reference to example embodiments thereof, it will be understood that various changes in form and details may be made therein without departing from the scope of the following claims.

What is claimed is:

1. A method of manufacturing a semiconductor package, the method comprising:
forming a conductive layer on a first redistribution substrate;
forming, on the conductive layer, a resist film having an opening, wherein the opening extends through the resist film to expose an organic residue, and wherein an oxide film is provided between the conductive layer and the organic residue;
removing the organic residue by adding an alcohol solution into the opening;
removing the oxide film by adding an acid solution into the opening; and
forming a conductive post in the opening,
wherein the oxide film is provided on the conductive layer, and the oxide film and the conductive layer comprise a same metal material.

2. The method of claim 1, wherein the organic residue and the resist film comprise a same material.

3. The method of claim 1, wherein the acid solution comprises a weak acid, and a pKa of the weak acid is 2.58 or greater.

4. The method of claim 1, wherein the alcohol solution comprises about 40% to about 60% of alcohol.

5. The method of claim 1, wherein the alcohol solution comprises ethanol, and the acid solution comprises citric acid.

6. The method of claim 1, wherein the removing of the oxide film comprises exposing a top surface of the conductive layer, and
wherein the conductive post is formed on the top surface of the conductive layer that has been exposed.

7. The method of claim 6, wherein the forming of the conductive post comprises performing a plating process in the opening and on the top surface of the conductive layer that has been exposed.

8. The method of claim 1, further comprising:
mounting, on the first redistribution substrate, a semiconductor chip that is laterally spaced apart from the conductive post; and
forming a second redistribution substrate on the conductive layer, wherein the second redistribution substrate is electrically connected to the conductive post.

9. A method of manufacturing a semiconductor package, the method comprising:
forming a conductive seed layer on a redistribution substrate;
forming a resist film on the conductive seed layer;
forming an opening extending through the resist film, wherein the opening exposes an organic residue, and wherein an oxide film is provided between the conductive seed layer and the organic residue;
performing a pre-processing process in the opening; and
forming a conductive structure in the opening after the pre-processing process,
wherein the performing of the pre-processing process comprises:
performing a first pre-processing process to remove the organic residue; and
performing a second pre-processing process, after the first pre-processing process, to remove the oxide film.

10. The method of claim 9, wherein the first pre-processing process is performed using an alcohol solution, and
wherein the second pre-processing process is performed using an acid solution.

11. The method of claim 10, wherein the alcohol solution comprises about 40% to about 60% of alcohol, and
wherein the acid solution comprises a weak acid having a pKa of 2.58 or greater.

12. The method of claim 9, wherein the oxide film is formed on a portion of the conductive seed layer,
wherein the oxide film comprises a first portion and a second portion,
wherein the opening vertically overlaps the first portion and the second portion of the oxide film,
wherein the organic residue is formed on the first portion of the oxide film while the opening is formed,
wherein the organic residue is separated from a top surface of the second portion of the oxide film, and
wherein, before the pre-processing process, the opening exposes the top surface of the second portion of the oxide film and exposes the organic residue.

13. The method of claim 12, wherein the performing of the first pre-processing process comprises exposing a top surface of the first portion of the oxide film, and
wherein the performing of the second pre-processing process comprises exposing a top surface of the portion of the conductive seed layer.

14. The method of claim 13, further comprising:
performing, after the first pre-processing process, a first cleaning process on the top surface of the first portion of the oxide film that has been exposed; and
performing, after the second pre-processing process, a second cleaning process on the top surface of the portion of the conductive seed layer that has been exposed.

15. The method of claim 13, wherein the first pre-processing process is performed for about thirty seconds to about ninety seconds, and
wherein the second pre-processing process is performed for about thirty seconds to about ninety seconds.

16. A method of manufacturing a semiconductor package, the method comprising:
forming a first redistribution substrate comprising a first insulating layer, a first seed pattern, a first redistribution pattern on the first seed pattern, and a first redistribution pad on the first redistribution pattern;
forming a conductive seed layer on the first insulating layer and the first redistribution pad;
forming a resist film on the conductive seed layer;
forming an opening in the resist film, wherein the opening exposes at least one of an oxide film or an organic residue;
removing the organic residue by performing a first pre-processing process in the opening, wherein an alcohol solution is used in the first pre-processing process;
removing the oxide film by performing a second pre-processing process in the opening, wherein an acid solution is used in the second pre-processing process; and
forming a conductive post by performing a plating process in the opening,
wherein the opening vertically overlaps a portion of the conductive seed layer,
wherein the oxide film is formed on the portion of the conductive seed layer, and the oxide film and the conductive seed layer comprise a same metal material,
wherein the organic residue is formed on a first portion of the oxide film while the opening is formed,
wherein the organic residue and the resist film comprise a same material,
wherein the first pre-processing process is performed before the second pre-processing process, and
wherein the second pre-processing process is performed before the plating process.

17. The method of claim 16, wherein the alcohol solution comprises about 40% to about 60% of ethanol, and
wherein the acid solution comprises citric acid having a molar concentration of about 0.1 M to about 5 M.

18. The method of claim 16, wherein the forming of the opening comprises removing a portion of the resist film by performing a process of exposure and development of the resist film.

19. The method of claim 16, further comprising forming a second redistribution substrate on the conductive post,
wherein the second redistribution substrate comprises a second insulating layer, a second seed pattern, and a second redistribution pattern on the second seed pattern, and
wherein the second redistribution pattern is electrically connected to the conductive post.

20. The method of claim 16, further comprising:
mounting, on the first redistribution substrate, a semiconductor chip that is laterally spaced apart from the conductive post; and
forming, on the first redistribution substrate, a molding film covering a side surface of the conductive post and the semiconductor chip.
